(19) United States
(12) Patent Application Publication
(10) Pub. No.: US 2009/0097218 A1
(43) Pub. Date: Apr. 16, 2009

(54) Capacitor-embedded printed wiring board and method of manufacturing the same

(76) Inventor: Garo Miyamoto, Ushiku-shi (JP)

Correspondence Address: JACOBSON HOLMAN PLLC, 400 SEVENTH STREET N.W., SUITE 600, WASHINGTON, DC, 20004, US

(21) Appl. No.: 12/285,447

(22) Filed: Oct. 6, 2008

(30) Foreign Application Priority Data
Oct. 10, 2007 (JP) 2007-264268

(51) Int. Cl. H05K 1/16; H05K 13/00

(52) U.S. Cl. 361/761; 29/856

(57) ABSTRACT

There is provided a capacitor-embedded printed wiring board incorporating therein a capacitor having stabilized electrical characteristics. The capacitor-embedded printed wiring board includes: a capacitor having a first electrode 5, a high dielectric constant layer 7 and a second electrode 9 which are sequentially laminated on an insulating substrate 1, the second electrode being electrically connected to a land 6 for electrode contact formed in a wiring layer in which the first electrode is formed; a member 12 having at least one insulating layer and laminated over the capacitor and the wiring layer; and a via 18 having an opening extending through the member and the second electrode to reach the land, the via electrically interconnecting the second electrode and the land in the opening. A method of manufacturing the same is also provided.

### CROSS REFERENCE TO RELATED APPLICATIONS

This application is based upon and claims the benefit of priority from the prior Japanese Patent Application No. 2007-264268, filed on Oct. 10, 2007, the entire contents of which are incorporated herein by reference.

### BACKGROUND OF THE INVENTION

1. Field of the Invention

The present invention relates to a capacitor-embedded printed wiring board as well as a method of manufacturing the same and, more particularly, to a capacitor-embedded printed wiring board incorporating therein a capacitor having improved electrical connection reliability, as well as a method of manufacturing the same.

2. Related Art

In recent years, the market needs have increased for highly integrated passive elements for higher-performance electronic devices. Various passive elements of the type having been mounted on printed wiring boards are generally recognized as a major impediment to downsizing of electronic devices. Particularly, an increase in the number of input-output terminals of semiconductor active elements calls for a larger space for the provision of passive elements around such an active element. This is not a problem easy to solve.

Representatives of such passive elements include capacitors. Such a capacitor is requested to be properly located for reducing inductance reflecting an operating frequency becoming higher. For example, a decoupling capacitor used for stabilized power supply is requested to be located at a minimum distance from an input terminal in order to reduce the inductance resulting from induction caused by the frequency becoming higher.

To meet the requirements for the downsizing of electronic devices and for the frequency becoming higher, diversified types of low-ESL (Equivalent Series Inductance) stacked capacitors have been developed. Among them, conventional MLCCs (Monolithic Ceramic Chip Capacitors: multilayer ceramic capacitors) have essential limitations as discrete elements in overcoming the above-described problem.

A large number of capacitors are used as electrical circuit elements. If it is possible to embed these capacitors into a printed wiring board, the area of the board can be reduced effectively. Therefore, intensive development of embedded type capacitors has been made recently.

Since such an embedded type capacitor is embedded in a printed wiring board, the size of an intended product can be reduced. Also, since the embedded type capacitor can be located close to an input terminal of an active element, a parasitic inductance component can be largely reduced by minimizing the wiring length. The embedment of a capacitor can be expected to provide advantages including not only a reduction in the size of the board but also improvements in electrical characteristics. However, some capacitor forming methods do not contribute to any improvement in electrical characteristics even when a capacitor is embedded in a wiring board.

In forming a capacitor by screen printing, a high dielectric constant layer is formed over a first electrode, followed by formation of a second electrode on the high dielectric constant layer. In this case, a metal conductor surface is oxidized by thermal curing conducted during the high dielectric constant layer forming step. Because such a high dielectric constant layer is easily broken when subjected to a wet treatment such as acid washing, a contact with the second electrode has to be formed on the oxidized conductor. However, this method sometimes renders the electrical characteristics of the capacitor unstable due to the oxide film formed on the conductor.

With attention being paid to the aforementioned problem, a capacitor-embedded printed wiring board described in Japanese Patent Laid-Open No. 63-222413 (P2) has solved the problem by printing a silver paste on a contact portion to be brought into contact with the second electrode prior to the formation of the high dielectric constant layer.

This approach, however, makes the process complicated and hence lowers the cost merit. Also, since a copper paste for forming the second electrode is stacked on the silver paste, a lamination adhesive layer has to be made thicker, which leads to an increased wiring board thickness and lowered connection reliability.

Though the problem associated with the oxide film of the electrode contact portion can be solved when the thermal curing is conducted under a nitrogen (N₂) atmosphere, sufficient cooling of the board in an oven is needed in order to avoid oxidation upon removal of the board from the oven, thus taking much time. This is disadvantageous to volume productivity.

FIGS. 2A and 2B are sectional views illustrating a method of manufacturing a conventional capacitor-embedded printed wiring board. Initially, a so-called double-sided copper clad laminate 21 is provided which has first and second conductive layers each formed of a copper foil or the like on opposite sides of an insulating base material such as of polyimide (see FIG. 2A(1)). Subsequently, a first electrode 22 of a capacitor and a circuit 23 including a contact portion for contact with a second electrode to be described later, a land for via formation to be described later and required wiring, are formed in the first conductive layer 21a.

A silver paste 24 is printed on the contact portion for contact with the second electrode (see FIG. 2A(2)) and, thereafter, a high dielectric constant layer 25 is formed over the first electrode 22 (see FIG. 2A(3)). Subsequently, the second electrode 26 is formed on the high dielectric constant layer 25 and on the silver paste 24 printed on the electrode contact portion (see FIG. 2A(4)). A single-sided copper clad laminate 27 is laminated on the side formed with the capacitor via an intervening lamination adhesive 28 (see FIG. 2A(5)).

After formation of a conformal mask 29 for use in laser beam machining (see FIG. 2B(6)), an opening 30 to form a bottomed via for interlayer conduction is formed by using a laser (see FIG. 2B(7)), followed by a conductivity imparting treatment and formation of a plating film 31 (see FIG. 2B(8)). Thereafter, etching according to a photofabrication technique is conducted to form a circuit pattern, thus giving a capacitor-embedded printed wiring board 32 (see FIG. 2B(9)).

As described above, there have been provided a capacitor-embedded printed wiring board and a method of manufacturing the same.

It is, however, difficult for the conventional art to manufacture a capacitor having stabilized electrical characteristics by printing.

The present invention has been made in view of the foregoing problems. Accordingly, it is an object of the present invention to provide a capacitor-embedded printed wiring board incorporating therein a capacitor having stabilized electrical characteristics, as well as a method of manufacturing the same with a high yield.

### SUMMARY OF THE INVENTION

In order to accomplish the foregoing object, the instant application provides the following inventions.

A first invention is directed to a capacitor-embedded printed wiring board including:

a capacitor having a first electrode, a high dielectric constant layer and a second electrode which are sequentially laminated on one surface of an insulating substrate, the second electrode being electrically connected to a land for electrode contact formed in a wiring layer in which the first electrode is formed;

a member having at least one insulating layer and laminated over the capacitor; and

a via having an opening extending through the member and the second electrode to reach the land, the via electrically interconnecting the second electrode and the land in the opening.

A second invention is directed to a method of manufacturing a capacitor-embedded printed wiring board, including:

providing a wiring board having a land for electrode contact which is formed on one surface of an insulating substrate for connection with first and second electrodes;

printing a high dielectric constant paste in such a manner as to cover the first electrode and then thermally curing the high dielectric constant paste to form a high dielectric constant layer;

forming the second electrode by printing a conductive paste on the high dielectric constant layer in such a manner as to reach the land, thereby forming a capacitor;

laminating over the capacitor a member having at least one insulating layer;

making an opening extending through the member and the second electrode to reach the land by using a laser; and

plating the opening after cleaning to form a via electrically interconnecting the second electrode and the land.

By virtue of the features described above, the present invention has the following advantage.

According to the present invention, it is possible to provide the capacitor-embedded printed wiring board incorporating therein the capacitor having stabilized electrical characteristics by forming the via in the contact portion between the second electrode of the capacitor and the land.

### BRIEF DESCRIPTION OF THE DRAWINGS

FIG. 1A is a flow drawing illustrating process steps of manufacturing a capacitor-embedded printed wiring board according to one embodiment of the present invention;

FIG. 1B is a flow drawing illustrating process steps of manufacturing the capacitor-embedded printed wiring board according to one embodiment of the present invention;

FIG. 2A includes sectional views showing a capacitor-embedded printed wiring board according to a conventional manufacturing method; and

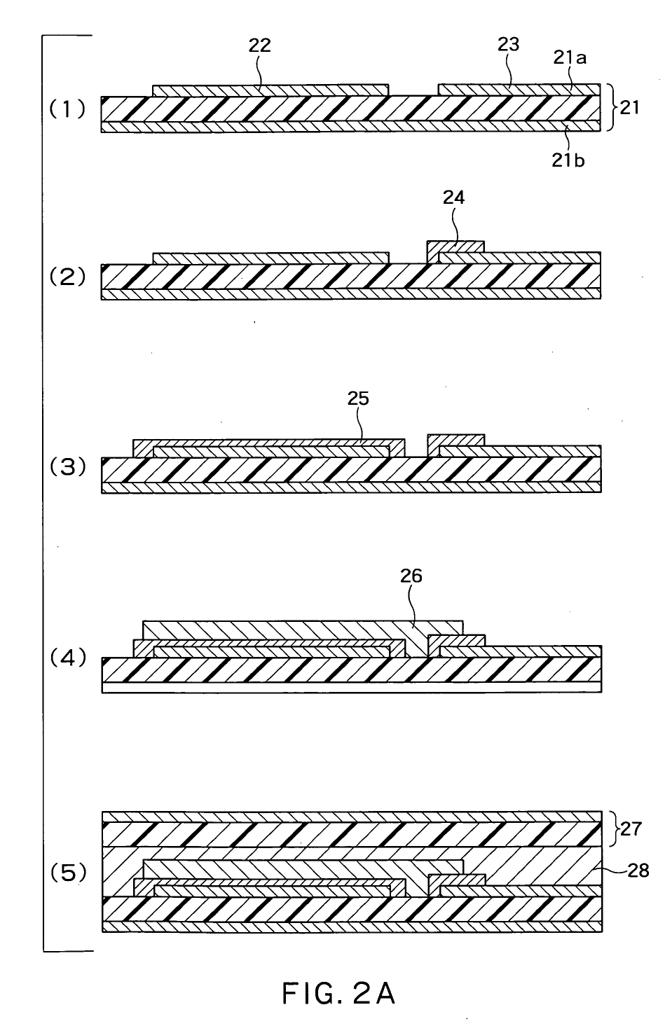

FIG. 2B includes sectional views showing the capacitor-embedded printed wiring board according to the conventional manufacturing method.

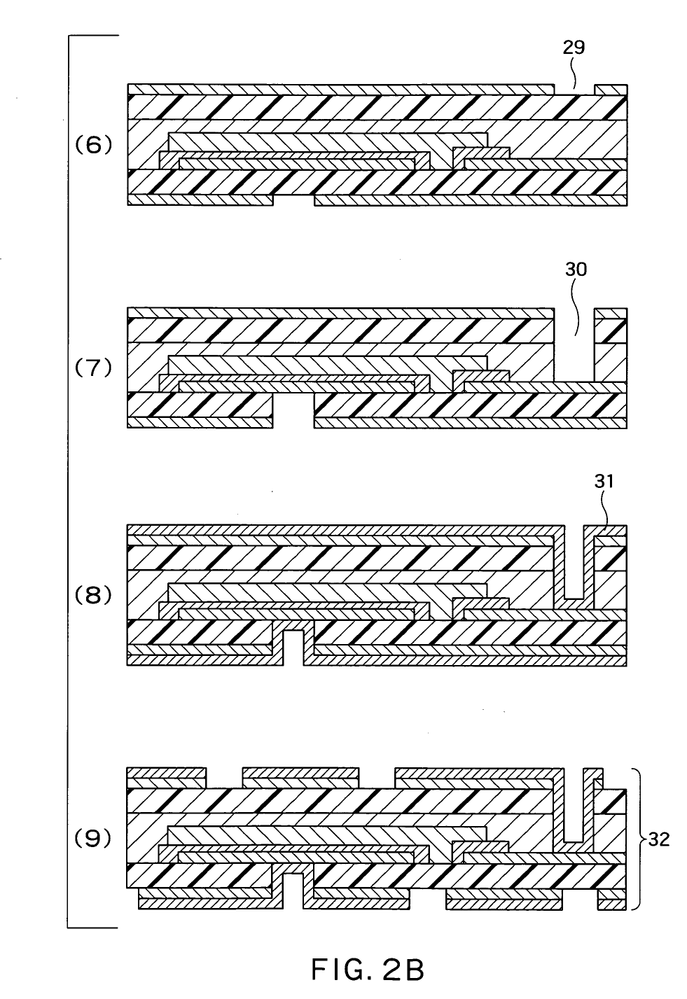

### DETAILED DESCRIPTION OF THE INVENTION

Hereinafter, the present invention will be further described with reference to an embodiment shown in the drawings.

### First Embodiment

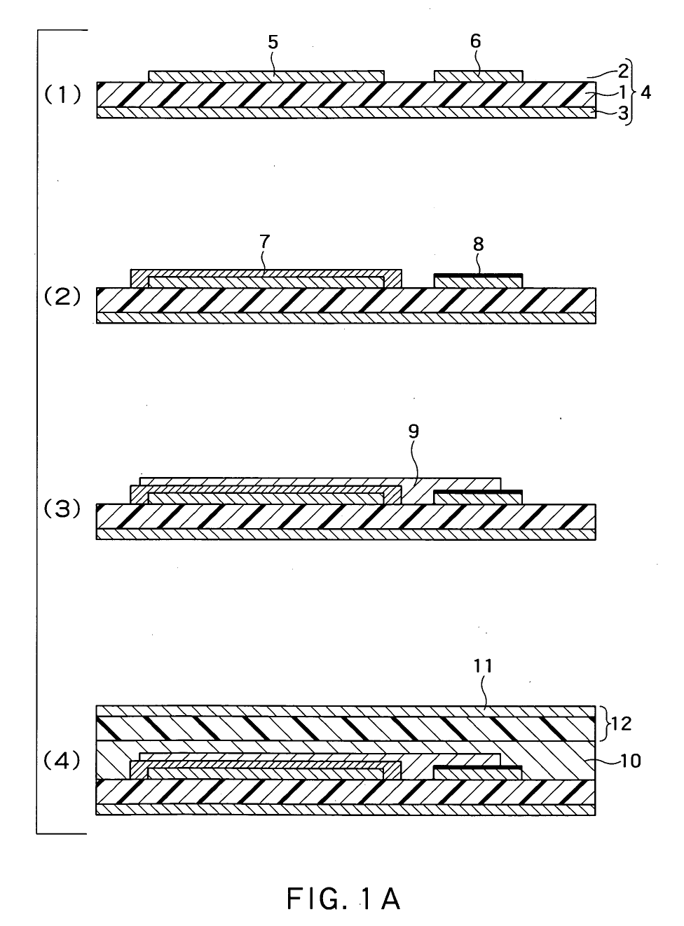

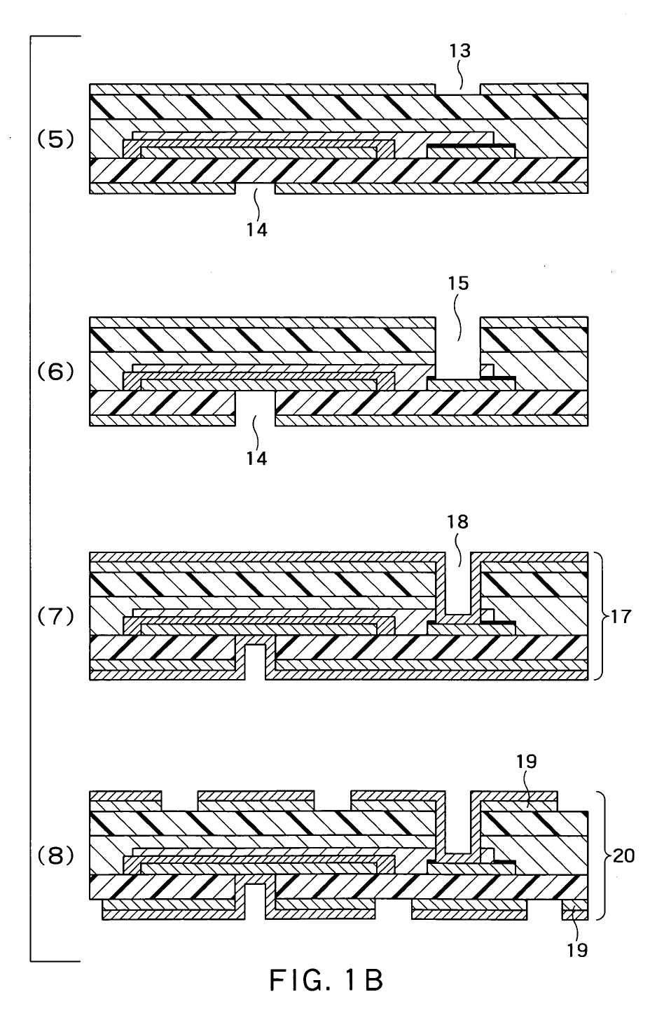

FIGS. 1A and 1B include sectional views illustrating process steps of a method of manufacturing a capacitor-embedded printed wiring board according to one embodiment of the present invention. Initially, as shown in FIG. 1A(1), a so-called double-sided copper clad laminate 4 was provided which had first and second metal foils 2 and 3, such as copper foils, on opposite sides of an insulating base material 1 such as of polyimide. Predetermined regions of the first metal foil 2 were subjected to etching according to a common photofabrication technique, to form a first electrode 5 of a capacitor, a land 6 for electrode contact, and a required wiring pattern.

The base material used was a 25 μm-thick polyimide material, and the metal foils used were each a 12 μm-thick electrolytic copper foil. The capacitance of the capacitor is determined by the area of the electrodes, the interelectrode distance and the material formed between the electrodes. In this embodiment, the area of the electrodes was 100 mm².

Subsequently, as shown in FIG. 1A(2), a high dielectric constant layer 7 was formed over the first electrode 5 of the capacitor. Screen printing was used here as a process for forming the high dielectric constant layer. However, ink-jet printing, dispense printing or a like printing process is applicable.

The paste used was “CX-16” produced by Asahi Chemical Research Laboratory Co., Ltd. Printing was performed using a 500-mesh plain weave stainless screen plate, followed by thermal curing at 150° C. for 30 min. in a box-type hot air oven. The thickness of the high dielectric constant layer was 6 μm after the thermal curing. At that time, an oxide film 8 was formed over the land formed in the first metal foil 2 by the heat of the oven.

Subsequently, as shown in FIG. 1A(3), a second electrode 9 of the capacitor was formed on the high dielectric constant layer 7 and on the land 6. Screen printing was used here as a process for forming the second electrode. However, ink-jet printing, dispense printing or a like printing process is applicable.

The paste used was a silver paste “LS-506J” produced by Asahi Chemical Research Laboratory Co., Ltd. Printing was performed using a 250-mesh plain weave stainless screen plate, followed by thermal curing at 150° C. for 30 min. in a box-type hot air oven. Any other conductive paste, such as a silver paste of other type, copper paste, or carbon paste, can be used to form the second electrode. In this state, the oxide film 8 intervened between the second electrode 9 of the capacitor and the land 6.

Subsequently, as shown in FIG. 1A(4), a single-sided copper clad laminate (member) 12 having an insulating base material and a metal foil 11 was laminated on the side formed with the capacitor via an intervening lamination adhesive 10. The lamination was conducted under the conditions: pressing at 170° C. and 2.0 MPa for 4 min. with a vacuum laminator; and oven curing at 180° C. for 2.5 hr in a box-type hot air oven. Though the single-sided copper clad laminate was used here, it is possible to use as the member 12 a double-sided copper clad laminate, a single- or double-sided or multi-layer wiring board already formed with wiring, or an insulating film.

Thereafter, as shown in FIG. 1B(5), the metal foil 11 of the member 12 and the second metal foil 3 were subjected to etching according to the common photofabrication technique, to form conformal masks 13 and 14 for use in laser beam machining.

Subsequently, as shown in FIG. 1B(6), carbon dioxide gas (CO₂) laser beam machining was performed using the conformal masks to make openings 15 and 16. Though carbon dioxide gas (CO₂) laser beam machining was performed here, other light sources including a YAG (Yttrium Aluminum Garnet) laser are applicable. By cleaning the opening portions after the laser beam machining, a portion of the oxide film 8 on the land 6 which lay in the bottom of the opening 15 was removed.

Subsequently, as shown in FIG. 1B(7), a conductivity imparting treatment and a plating process were conducted to form a via 18. The via 18 made a connection between the capacitor electrode and the land 6, thus making it possible to stabilize the electrical characteristics of the capacitor.

Subsequently, as shown in FIG. 1B(8), a circuit pattern 19 was formed by etching the second metal foil 3, metal foil 11 and plating film 17 according to the photofabrication technique, thus giving a capacitor-embedded printed wiring board 20 incorporating therein a capacitor having stabilized electrical characteristics. The capacitor thus formed by the above-described process was found to have a capacitance of 7.5 nF with capacitance variations falling within a range of 5%.

According to the conventional techniques, the electrical characteristics of the capacitor are stabilized by removing or reducing an oxide film on a circuit conductor in an electrode contact portion. In any case, however, an additional process step is needed to remove or reduce such an oxide film.

By contrast, the present invention makes it possible to manufacture a capacitor having stabilized electrical characteristics with a high yield without requiring any additional process step, thus offering an increased cost merit.

What is claimed is:

1. A capacitor-embedded printed wiring board comprising:
a capacitor having a first electrode, a high dielectric constant layer and a second electrode which are sequentially laminated on one surface of an insulating substrate, the second electrode being electrically connected to a land for electrode contact formed in a wiring layer in which the first electrode is formed;
a member having at least one insulating layer and laminated over the capacitor; and
a via having an opening extending through the member and the second electrode to reach the land, the via electrically interconnecting the second electrode and the land in the opening.

2. A method of manufacturing a capacitor-embedded printed wiring board, comprising:
providing a wiring board having a land for electrode contact which is formed on one surface of an insulating substrate for connection with first and second electrodes;
printing a high dielectric constant paste in such a manner as to cover the first electrode and then thermally curing the high dielectric constant paste to form a high dielectric constant layer;
forming the second electrode by printing a conductive paste on the high dielectric constant layer in such a manner as to reach the land, thereby forming a capacitor;
laminating over the capacitor a member having at least one insulating layer;
making an opening extending through the member and the second electrode to reach the land by using a laser; and
plating the opening after cleaning to form a via electrically interconnecting the second electrode and the land.
